(19) United States
(12) Patent Application Publication
(10) Pub. No.: US 2013/0263921 A1
(43) Pub. Date: Oct. 10, 2013

(54) Electronic Device and Corrosion Resistant Electrode Stack Therein

(71) Applicants: Lauren Plavisch, Cambridge, MA (US); Melissa Ricci, Belmont, MA (US); John C. Warner, Wilmington, MA (US)

(72) Inventors: Lauren Plavisch, Cambridge, MA (US); Melissa Ricci, Belmont, MA (US); John C. Warner, Wilmington, MA (US)

(21) Appl. No.: 13/443,559

(22) Filed: Apr. 10, 2012

(51) Int. Cl. H01L 31/0224; H01L 51/44

(52) U.S. Cl. 136/256; 136/263

(57) ABSTRACT

Disclosed and claimed herein is an electrode stack having a first electrode, an electrolyte comprising a REDOX couple, a conductive layer disposed on a substrate, wherein the conductive layer is a flaked conductor, and a binder and wherein the conductor is chosen to resist corrosion in the presence of the electrolyte.

### FIELD OF THE INVENTION

The present application for patent is in the field of solar energy. More specifically, the present application for patent discloses and claims a material for forming a cathode in a dye sensitized solar cell and the method of making the material.

### BACKGROUND

Dye-sensitized photovoltaic cells for producing electricity from sunlight have been described by U.S. Pat. No. 4,927,721 and U.S. Pat. No. 5,350,644 to Graetzel, et al. These patents disclose a photovoltaic cell having a light-transmitting, electrically-conductive layer disposed on a glass plate or a transparent polymer sheet. A mesoporous layer of titanium dioxide (TiO₂) is applied to the light transmitting, electrically-conductive layer, either singly or by successive deposition. At least a portion of the titanium dioxide layer is sensitized with a chromophore or dye such as cis-dicyano bis (2,2′-bipyridine)Ru(II), cis-dicyano bis (4,4′-COOH-2,2′bipyridine) Ru(II), or the like to absorb light and initiate a rapid electron transfer to the TiO₂.

The above described cells have two electrodes, the cathode and the photo-anode, separated by an electrolyte comprising a REDOX couple such as aqueous iodide/triiodide (I⁻/I₃⁻). The photo-anode, which faces the sun or light source, comprises the dyed titanium dioxide, while the cathode is usually a conductive layer. Both electrodes are in electrical contact with the electrolyte. Furthermore, the electrolyte may penetrate the dyed TiO₂ layer and make contact with the light transmitting electrically conductive layer, described supra.

In principle, the cathode may be any conductive material. However, a potentially corrosive electrolyte, such as the aqueous I⁻/I₃⁻ couple, can limit the choice of conductor. One conductor that appears to provide sufficient conduction without being corroded by the electrolyte is platinum. Graetzel et al. disclose such a platinum coated cathode in U.S. Pat. No. 4,927,721. Another such metal is continuous gold. However, non corrosive metals such as gold and platinum are expensive in continuous form and can drive the overall device cost above commercial limits. Continuous nickel metal or nickel oxide (NiO), as disclosed by Nattestad et al., Nanotechnology 19 (2008) 295304 have been used. However, deposition of the metal requires electroless plating and/or electroplating technologies that use potentially harmful chemicals and may require considerable deposition time. Preparation of NiO films requires the use of high temperature processes that are incompatible with plastic substrates.

Therefore, there remains a need for a conductive material that may be applied quickly to a plastic substrate and use inexpensive low temperature processing. Moreover, there remains a need for a conductive material that, when in use, is not susceptible to corrosion by a REDOX electrolyte. These needs are addressed by the subject matter disclosed and claimed herein.

### DETAILED DESCRIPTION

As used herein, the conjunction “or” is not intended to be exclusive unless otherwise noted. For example, the phrase “or alternatively” is intended to be exclusive. Further, when used in connection with chemical substitution at a specific position, the conjunction “or” is intended to be exclusive. As used herein, the adjective “exemplary” is used simply to point to an example and is not meant to indicate preference. As used herein, mesoporous materials are porous materials with pores of about 2 to about 100 nm in size.

In a first embodiment, disclosed and claimed herein is an electrode stack having: a first electrode; an electrolyte comprising a REDOX couple; a conductive layer disposed on a substrate, wherein the conductive layer comprises a flaked conductor, and a binder, and wherein the conductor is chosen to resist corrosion in the presence of the electrolyte.

In a second embodiment, disclosed and claimed herein is a dye sensitized solar cell, having: a first conductive layer, disposed on a first substrate, wherein the first conductive layer is configured to transmit light, and wherein the first substrate is transparent to at least a portion of the surface solar spectrum; a metal oxide semiconductor sensitized with a dye; an electrolyte comprising a REDOX couple; a second conductive layer, disposed on a second substrate, wherein the second conductive layer comprises a flaked conductor, and a binder. and wherein the conductor is chosen to resist corrosion in the presence of the electrolyte.

Flaked conductors can comprise flaked metals such as nickel, platinum, gold, palladium, tungsten titanium, cobalt, rhodium, iridium or any metal that resists corrosion in the presence of the electrolyte REDOX couple. In addition, flaked conductors can comprise composite metals; examples of which include titanium plated with platinum, titanium plated with platinum and then with gold, nickel plated with platinum, nickel plated with palladium and the like. Other flaked conductors may be used. For example, graphite, graphine and partially pyrolyzed polyacryonitrile, possibly in its oxidized form, may also be used. Conductive polymers may be used such as poly(fluorene)s, polyphenylenes, polypyrenes, polyazulenes, polynaphthalenes, poly(pyrrole)s, polycarbazoles, polyindoles, polyazepines, polyanilines, poly(thiophene)s, poly(3,4-ethylenedioxythiophene), poly(p-phenylene sulfide), poly(acetylene)s, poly(p-phenylene vinylene)s and the like may be formed as flakes, for example, by forming films on flexible substrates and stretching the substrates to release the flakes.

Exemplary aspect ratios for flaked conductors>5:1. Further, exemplary aspect ratios for flaked conductors may be >25:1. Still further exemplary aspect ratios may be >100:1. Still further exemplary aspect ratios may be >500:1. In addition, conducting nanowires may be used to provide conductive composites.

In the first embodiment, the first electrode can comprise a patterned or unpatterned metal, a metal flake material comprising metal flakes and a binder, a mesoporous metal oxide semiconductor, a dyed mesoporous metal oxide semiconductor, an electrochromic material, an allotrope of carbon, such as graphite, a fullerene or amorphous carbon, a transparent conductive oxide or the like. In the metal flake materials, without limitation, these may include the metals cited supra and composites comprising those metals.

Various metal oxides can be used. Without limitation, the metal oxides may or may not be mesoporous materials. Without limitation, metal oxides can include titanium dioxide, tungsten trioxide, tin dioxide, zinc oxide, strontium titanate, niobium monoxide and niobium pentoxide. These oxides can be doped with various materials to enhance conductivity, create p-n junctions, emit light, or store charge.

The embodiments disclosed and claimed herein employ electrolyte materials that comprise one or more REDOX couples. The electrolyte may be in the form of a crystalline or amorphous solid, a gel or a fluid, having a viscosity of between 0.1 and 100,000 centipoise (cP). The choice of viscosity may depend on the application. For example, in applications where a high ionic mobility is required, a lower viscosity may be chosen. An exemplary viscosity range is from about 0.1 cP to about 10,000 cP. A further exemplary viscosity range is from about 0.4 cP to about 5000 cP. A still further exemplary viscosity range is from about 0.5 cP to about 50 cP. Various viscosity modifiers are known in the art. These include cellulosic materials, polyalkalene oxides, poly (meth)acrylic acid, fumed silica, and the like.

Without limitation, REDOX couples can include I₃⁻/I⁻, Co⁺⁺⁺/Co⁺⁺, Fe⁺⁺⁺/Fe⁺⁺, Cu⁺⁺/Cu⁺, Ag⁺/Ag, thiolate/disulphide, ferrocinium/ferrocene, ferricyanide/ferrocyanide, or combinations thereof. Counter ions may be selected for various reasons. For example, small counter ions may be used to support a high electric mobility. For example, without limitation, when the REDOX couple, comprises negatively charged anions, counter ions may include the cations of alkali metals, alkaline earth metals, ammonium ions, protonated primary, secondary and tertiary amines and quaternary ammonium salts may be used as counterions. Further, and without limitation, when the redox couple involves positively charged ionic species, halides, chalcogenides, oxo-acid anions, organo sulfonic acids, organo phosphonic acids, and the like may be used as counterions.

Binders can be used in conjunction with metal flake materials in an amount necessary to form a cohesive material without destroying conductivity. One such binder is a random copolymer comprising repeat units of ethylene and (meth)acrylic acid and fluoroplastic materials such as Dyneon™ THV, available from 3M. Moreover, binders may comprise a polymer and a crosslinker, wherein the polymer may have functional groups capable of binding to crosslinkers. Without limitation, such functional groups may include esters, alcohols, phenols, amines, amides, imides, or carboxylic acids. Moreover, and without limitation, crosslinkers may include epoxy phenolic novolak resins, epoxy cresylic novolak resins, epoxy bisphenol A resins, epoxy bisphenol A novolak resins, epoxy bisphenol C resins, alkylolmethyl melamine resins, alkylolmethyl glycoluril resins, alkylolmethyl guanamine resins, alkylomethyl benzo-guanamine resins, glycosyl urea resins, and alkyd resin. Polymers and crosslinkers may be used singly or in combination.

Forming a unitary, cohesive conductive layer using a metal flake compound and a binder may be accomplished by using a ration expressed as a weight percent or as a volume percent. For example a composite of nickel flake and a poly(ethylene-co-acrylic acid) copolymer can form a cohesive conductive layer at about 70% nickel, w/w, (30% polymer w/w), wherein the volume percentage is about 21% v/v of nickel and 79% v/v of polymer. The ratio having minimum nickel depends on the aspect ratio of the metal flakes and the thickness of the film, a cohesive conducting layer can be formed using about 15% v/v to about 65% v/v of metal flake. For applications requiring an interaction between one or more of the electrodes with light, for example in solar cells, it may be desirable to have at least one substrate that is at least partially transparent to a portion of the surface solar spectrum and an electrode disposed on the substrate that is configured to transmit at least a portion of the impinging light. The surface solar spectrum is known in the art and ranges from about 300 nm (4.15 eV of energy) to about 2,500 nm (0.1 eV of energy) and peaks at about 600 nm (2.08 eV). Partial transparency is understood to transmit about 25% to about 99.9% of the light at a given wavelength.

Accordingly, transparent conductive oxides may be disposed on the partially transparent substrate. These include indium tin oxide, indium oxide, tin oxide, cadmium stannate, zinc oxide, doped indium tin oxide, doped indium oxide, doped tin oxide, doped cadmium stannate, doped zinc oxide, fluorine doped tin oxide, one or more layers thereof or combinations thereof. In addition, thin metal layers may be deposited in such a way as to be electrically conductive while still being partially transparent. For example a nickel film having 10 nm of thickness exhibits a resistivity of about 65 μΩ-cm at room temperature with about a 40% mean visible transmittance. In addition, a conductor may be configured to transmit light by patterning the metal. Metal patterns may be imaged with line widths from about 50 micrometers to about 5000 micrometers using ink jet printing, imprint lithography, offset printing, photoresist masking pattern-wise plating or the like. Patterning may be accomplished by printing techniques known in the art. Without imitation such techniques include, photolithography, ink jet printing, imprint lithography, mechanical ablation, gravure printing, offset printing and the like. Printing techniques may be coupled with etching and ablation techniques such as plasma etching, reactive ion etching, sputtering, laser ablation mechanical ablation, wet etching, and the like.

In a dye sensitized solar cell, various porous or mesoporous metal oxides can be used as the anode. Without limitation, metal oxides can include titanium dioxide, tungsten trioxide, tin dioxide, zinc oxide, strontium titanate, niobium monoxide and niobium pentoxide, layers thereof and combinations thereof.

Numerous dyes for sensitizing metal oxides are known in the art. Indeed the dye sensitizer is not particularly limited as long as it is capable of generating an electromotive force by absorbing light. Such a dye sensitizer may be an organic dye, or a metal complex dye. Examples of the organic dye include acridine dyes, azo dyes, indigo dyes, quinone dyes, coumarin dyes, merocyanine dyes, phenylxanthene dyes, indoline dyes, carbazole dyes, anthocyanin dyes, and triphenyl amino styryl dyes such as (Z)-3-(4-(4-(bis(4-tert-butylphenyl)amino)styryl)-2,5-dimethoxyphenyl)-2-cyanoacrylic acid. Metal complex dyes such as ruthenium-based dyes, such as a ruthenium bipyridine dye or a ruthenium terpyridine dye are used because they exhibit light absorption over broad wavelength ranges. Binding to the metal oxide may be accomplished by substituting binding groups on the dye molecules. Such binding groups include carboxylate groups, cyano groups, phosphate groups oximes, dioximes, hydroxy quinolines, salicylates, and α-keto-enolates.

### EXAMPLES

Materials used in these examples were obtained from Aldrich Chemical Co. unless otherwise indicated. Percentages are wt/wt unless otherwise noted.

### Example 1

### Preparation of (Z)-3-(4-(4-(bis(4-tert-butylphenyl)amino)styryl)-2,5-dimethoxyphenyl)-2-cyanoacrylic Acid

Tris(dibenzylideneacetone)dipalladium(0) (Pd₂(dba)₃) (0.765 g, 0.83 mmol) and Sodium tert-butoxide (NaOtBu) (14.11 g, 146.81 mmol) were combined in a round bottom flask, that had been flushed with N₂. To this was added 1-bromo-4-tert-butylbenzene (17.88 g, 83.89 mmol), 4-amino styrene (5.00 g, 41.95 mmol), phosphine (0.57 g, 1.66 mmol) and toluene (125.00 ml). The reaction was heated to 85° C. for 3.5 hours before cooling to room temperature. The mixture was then filtered to remove the inorganic salts and washed with methylene chloride. The methylene chloride/toluene solvents were removed under reduced pressure to give a dark brown residue. The organic residue was then taken up in methylene chloride and washed with saturated brine. The organic layer was dried over magnesium sulfate, filtered and separated using a Teledyne ISCO gold column, using methylene chloride and hexanes to elute. ¹H and ¹³C confirmed the formation of the desired compound. Recovered 13.84 g as a white solid. (86% yield).

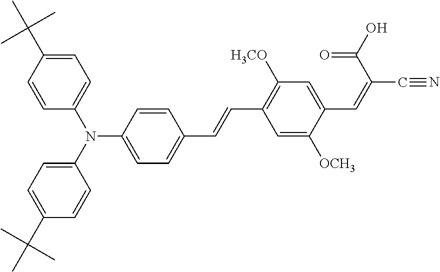 [SMILES: COc1cc(/C=C/c2ccc(N(c3ccc(C(C)(C)C)cc3)c3ccc(C(C)(C)C)cc3)cc2)c(OC)cc1/C=C(/C#N)C(=O)O]

### Example 2

In a test tube were combined 15 mg (24.4 micromole) of (Z)-3-(4-(4-(bis(4-tert-butylphenyl)amino)styryl)-2,5-dimethoxyphenyl)-2-cyanoacrylic acid, (BASCA), 1.93 g water, 750 microliters of a 2% Triton-X-100 solution and 0.3 ml of a 5M NH₃ solution. A dark, stable dye dispersion was obtained.

### Example 3

### Preparation of a Cell from a Formulation for Making a Nickel Flake Composite Film

Poly(ethylene-co-acrylic acid) 16 g, was placed in a glass bottle along with Ni Flake (available from Novamet), 37 g, along with deionized water, 39 g, and isopropanol, 8 g. The solution was rolled on a wet ball mill until the polymer was dissolved and the nickel dispersed. The dispersed solution was coated on PET film with a doctor blade with a wet film thickness of 380 microns.

A 1 inch by 1 inch piece of Indium tin oxide (ITO) treated plastic film (obtained from Solutia, St. Louis, Mo.) was coated with a dyed titanium dioxide semiconductor layer by using 1 strip of 3M removable tape, 38 microns thick, spaced 1 cm apart, and coating the fluid into the space between the tapes. The coating was dried at room temperature and then heated at 100 C for 30 minutes. After drying, the tape was removed and the dried coating was trimmed to 1 cm×1 cm square.

Assembly of the cell: A 1 inch by 1 inch piece of the Ni/polymer composite film was cut and then sputtered with Platinum. A piece of silk screen material was cut into the shape of a rectangle and used as a ‘well’ to hold the electrolyte. An iodide/triiodide electrolyte solution was interspersed between the two films and the assembly was clipped together.

### Example 4

A 1 inch by 1 inch piece of Indium tin oxide (ITO) treated plastic film (obtained from Solutia, St. Louis, Mo.) was coated with a dyed titanium dioxide semiconductor layer by using 1 strips of 3M removable tape, 38 microns thick, of 3M removable tape) spaced 1 cm apart and coating the fluid into the space between the tapes. The coating was dried at room temperature and then heated at 100 C for 30 minutes. After drying, the tape was removed and the dried coating was trimmed to 1 cm×1 cm square.

Assembly of the cell: Another piece of 1 in×1 in ITO treated plastic film was washed with ethanol and then sputtered with Platinum. A piece of silk screen material was cut into the shape of a rectangle and used as a ‘well’ to hold the electrolyte. An iodide/triiodide electrolyte solution wetted the two films together and the assembly was clipped together on a microscope slide.

The resulting cell was placed in a solar simulator and illuminated with 1 Kw/m² intensity. A current vs. voltage curve was generated and the following data were obtained:

TABLE 1

| Cathode | Area, | | J_{sc}, | Pₘₐₓ | | | Rₛₑᵣᵢₑₛ, |
|---|---|---|---|---|---|---|---|
| Material | cm² | V_{oc}, (mV) | (mA/cm²) | (mW) | FF | Eff., % | Ohms |
| ITO/Plastic | 0.9 | 782.3 | 7.343 | 2.676 | 0.52 | 3.36 | 36.6 |
| Example 4 | | | | | | | |
| Example 3 | 0.9 | 770.3 | 7.384 | 3.587 | 0.70 | 4.51 | 15.5 |

In the above table, the Area is the active area of the cell, V_{oc} is the open circuit voltage measured while the cell is being irradiated, J_{sc} is the short-circuit current density, measured while the cell is being irradiated, Pₘₐₓ is the maximum power derived from the cell, FF is the fill factor, Eff. Is the efficiency of the cell, and Rₛₑᵣᵢₑₛ is the internal series resistance of the cell. The ITO/plastic cathode serves as the control cell for this demonstration. It is a composite material, LR15, available from Solutia Company.

Although the present invention has been shown and described with reference to particular examples, various changes and modifications which are obvious to persons skilled in the art to which the invention pertains are deemed to lie within the spirit, scope and contemplation of the subject matter set forth in the appended claims.

What is claimed is:

1. An electrode stack comprising:
a. a first electrode;
b. an electrolyte comprising a REDOX couple;
c. a conductive layer, wherein the conductive layer comprises a flaked conductor, and a binder and wherein the conductor is chosen to resist corrosion in the presence of the electrolyte.

2. The electrode stack of claim 1, wherein the flaked conductor is a metal, comprising nickel, platinum, gold, palladium, tungsten, titanium, cobalt, rhodium, iridium or a composite comprising any of the foregoing.

3. The electrode stack of claim 1, wherein the REDOX couple comprises I₃⁻/I⁻, Co⁺⁺⁺/Co⁺⁺, Fe⁺⁺⁺/Fe⁺⁺, Cu⁺⁺/Cu⁺, Ag⁺/Ag, thiolate/disulphide, ferrocinium/ferrocene, ferricyanide/ferrocyanide, or combinations thereof.

4. The electrode stack of claim 1, wherein the binder comprises a polymer having ethylene and (meth)acrylic acid repeat units.

5. The electrode stack of claim 1, wherein the binder comprises the reaction product of a polymer and a crosslinker.

6. The electrode stack of claim 5, wherein the polymer comprises one or more reactive groups chosen from an ester, an alcohol, a phenol, an amine, an amide, an imide, or a carboxylic acid; and the crosslinker is an epoxy phenolic novolak resin, an epoxy cresylic novolak resin, an epoxy bisphenol A resin, an epoxy bisphenol A novolak resin, an epoxy bisphenol C resin, an alkylolmethyl melamine resin, an alkylolmethyl glycoluril resin, an alkylolmethyl guanamine resin, an alkylomethyl benzo-guanamine resin, a glycosyl urea resin, or an alkyd resin.

7. The electrode stack of claim 1 wherein the binder is present in an amount sufficient to produce a unitary, cohesive conductive layer.

8. The electrode stack of claim 1, wherein the first electrode is partially transparent to at least a portion of the surface solar spectrum.

9. A dye sensitized solar cell, comprising:
a. a first conductive layer, disposed on a first substrate, wherein the first conductive layer is configured to transmit light, and wherein the first substrate is partially transparent to at least a portion of the surface solar spectrum;
b. a metal oxide semiconductor sensitized with a dye;
c. an electrolyte comprising a REDOX couple;
d. a second conductive layer, wherein the second conductive layer comprises a flaked conductor, and a binder and wherein the conductor is chosen to resist corrosion in the presence of the electrolyte.

10. The electrode stack of claim 9, wherein the flaked conductor is a metal, comprising nickel, platinum, gold, palladium, tungsten, titanium, cobalt, rhodium, iridium or a composite comprising any of the foregoing.

11. The dye sensitized solar cell of claim 9, wherein the first conductive layer comprises one or more transparent conductive oxides chosen from indium tin oxide, indium oxide, tin oxide, cadmium stannate, zinc oxide, doped indium tin oxide, doped indium oxide, doped tin oxide, doped cadmium stannate, doped zinc oxide, fluorine doped tin oxide, one or more layers thereof or combinations thereof.

12. The dye sensitized solar cell of claim 9, wherein the first conductive layer comprises a patterned conductor.

13. The dye sensitized solar cell of claim 12, wherein the patterned conductor comprises:
a. a flaked metal and a binder, wherein the flaked conductor is a metal comprising nickel, platinum, gold, palladium, tungsten titanium, cobalt, rhodium, iridium or a composite comprising any of the foregoing, and the binder comprises the reaction product of a polymer and a crosslinker, wherein the polymer comprises one or more reactive groups chosen from an ester, an alcohol, a phenol, an amine, an amide, an imide, or a carboxylic acid; and the crosslinker is an epoxy phenolic novolak resin, an epoxy cresylic novolak resin, an epoxy bisphenol A resin, an epoxy bisphenol A novolak resin, an epoxy bisphenol C resin, an alkylolmethyl melamine resin, an alkylolmethyl glycoluril resin, an alkylolmethyl guanamine resin, an alkylomethyl benzo-guanamine resin, a glycosyl urea resin, or an alkyd resin, or
b. a metal chosen from nickel, platinum, gold, palladium, tungsten, titanium, cobalt, rhodium, iridium or a composite comprising any of the foregoing metals.

14. The dye sensitized solar cell of claim 12, wherein the patterned conductor comprises: a flaked metal and a binder, wherein the flaked metal comprises nickel, platinum, gold, palladium, tungsten, titanium, cobalt, rhodium, iridium or a composite comprising any of the foregoing metals, and the binder comprises a polymer.

15. The dye sensitized solar cell of claim 9, wherein the REDOX couple comprises I₃⁻/I⁻, Co⁺⁺⁺/Co⁺⁺, Fe⁺⁺⁺/Fe⁺⁺, Cu⁺⁺/Cu⁺, Ag⁺/Ag, thiolate/disulphide, ferrocinium/ferrocene, ferricyanide/ferrocyanide, or combinations thereof.

16. The dye sensitized solar cell of claim 9, wherein the metal oxide semiconductor is chosen from titanium dioxide, tungsten trioxide, tin dioxide, zinc oxide, strontium titanate, niobium monoxide and niobium pentoxide.

17. The dye sensitized solar cell of claim 9 wherein the dye comprises one or more binding groups chosen from carboxylate groups, cyano groups, phosphate groups, oximes, dioximes, hydroxy quinolines, salicylates, and α-keto-enolates.

18. The dye sensitized solar cell of claim 9, wherein the binder comprises ethylene and (meth)acrylic acid repeat units.

19. The dye sensitized solar cell of claim 9, wherein the binder comprises the reaction product of a polymer and a crosslinker.

20. The dye sensitized solar cell of claim 19, wherein the polymer comprises one or more reactive groups chosen from an ester, an alcohol, a phenol, an amine, an amide, an imide, or a carboxylic acid; and the crosslinker is an epoxy phenolic novolak resin, an epoxy cresylic novolak resin, an epoxy bisphenol A resin, an epoxy bisphenol A novolak resin, an epoxy bisphenol C resin, an alkylolmethyl melamine resin, an alkylolmethyl glycoluril resin, an alkylolmethyl guanamine resin, an alkylomethyl benzo-guanamine resin, a glycosyl urea resin, or an alkyd resin.
